(19) United States
(12) Patent Application Publication
(10) Pub. No.: US 2018/0279219 A1
(43) Pub. Date: Sep. 27, 2018

(54) METHOD AND DEVICE FOR PROCESSING SIGNAL

(71) Applicant: FURUNO ELECTRIC CO., LTD., Nishinomiya-City (JP)

(72) Inventor: Keisuke TANAKA, Nishinomiya-City (JP)

(73) Assignee: FURUNO ELECTRIC CO., LTD., Nishinomiya-City (JP)

(21) Appl. No.: 15/926,946

(22) Filed: Mar. 20, 2018

(30) Foreign Application Priority Data
Mar. 22, 2017 (JP) 2017-055253

(51) Int. Cl. H04W 52/00; H03G 3/30; H04B 1/48; G01S 1/04

(52) U.S. Cl. CPC H04W 52/00; G01S 1/04; H04B 1/48; H03G 3/3042

(57) ABSTRACT

A signal processing device is provided, which includes a transmission-reception switch connected to a transmission circuit and a reception circuit and configured to output, in a transmission period, a transmission signal inputted from the transmission circuit to outside the device and output, in a reception period, a reception signal inputted from the outside to the reception circuit, a reception signal amplifier configured to amplify the reception signal, and a processing circuit configured to switch a power source of the reception signal amplifier from OFF to ON when switching from the transmission period to the reception period.

### CROSS-REFERENCE TO RELATED APPLICATION(S)

This application claims priority under 35 U.S.C. § 119 to Japanese Patent Application No. 2017-055253, which was filed on Mar. 22, 2017, the entire disclosure of which is hereby incorporated by reference.

### TECHNICAL FIELD

The present disclosure generally relates to a signal processing device which performs transmission processing of a transmission signal and reception processing of a reception signal.

### BACKGROUND

Conventionally, in radar apparatuses, fish finders, wireless communication devices, etc., signal processing devices which perform a detection around the device by transmitting a transmission signal, receiving a reception signal, and analyzing the reception signal, and also communicate with surrounding devices are known. JP1999-112381A discloses this kind of signal processing device.

In the signal processing device (wireless device) of JP1999-112381A, a generated transmission signal is processed (e.g., frequency-modulated), then amplified by a transmission signal amplifier, and externally transmitted. This signal processing device of JP1999-112381A includes a switch which switches ON/OFF of a power source of the transmission signal amplifier. When receiving a reception signal, this switch turns the power source of the transmission signal amplifier OFF to reduce straying of the transmission signal into a reception circuit.

However, since voltage of the power source of the transmission signal amplifier does not immediately drop after it is turned OFF, the straying of the transmission signal into the reception circuit cannot sufficiently be reduced.

### SUMMARY

The purpose of the present disclosure mainly relates to providing a signal processing device, which sufficiently reduces straying of a transmission signal into a reception circuit.

According to a first aspect of the present disclosure, a signal processing device with the following configuration is provided. That is, the signal processing device may include a transmission-reception switch (e.g., a circulator and a duplexer), a reception signal amplifier, and a processing circuit. The transmission-reception switch may be connected to a transmission circuit and a reception circuit, output, in a transmission period, a transmission signal inputted from the transmission circuit to outside the device and output, in a reception period, a reception signal inputted from the outside to the reception circuit. The reception signal amplifier may amplify the reception signal. The processing circuit may switch a power source of the reception signal amplifier from OFF to ON when switching from the transmission period to the reception period.

According to a second aspect of the present disclosure, the following method of processing a signal is provided. That is, the method of processing a signal may include externally outputting a transmission signal inputted from a transmission circuit in a transmission period, outputting to a reception circuit a reception signal externally inputted and amplifying the reception signal by a reception signal amplifier in a reception period, and switching a power source of the reception signal amplifier from OFF to ON when switching from the transmission period to the reception period.

Thus, by switching ON/OFF of the power source of the reception signal amplifier, compared to the case of controlling the power source of the transmission signal amplifier, straying of the transmission signal into the reception circuit may sufficiently be reduced. Particularly, by switching the power source of the reception signal amplifier from OFF to ON when switching from the transmission period to the reception period, the drop of a S/N ratio of the reception signal caused by the transmission signal straying into the reception circuit may be reduced.

### BRIEF DESCRIPTION OF DRAWINGS

The present disclosure is illustrated by way of example and not by way of limitation in the figures of the accompanying drawings, in which like reference numerals indicate like elements and in which:

FIG. 1 is a block diagram of a radar apparatus including a signal processing device according to one embodiment of the present disclosure;

FIG. 2 is a timing chart of a comparison example in which a power source of a reception signal amplifier is always ON;

FIG. 3 is a schematic diagram of a radar image of the comparison example;

FIG. 4 is a timing chart of this embodiment;

FIG. 5 is a schematic diagram of a radar image of this embodiment; and

FIG. 6 is a timing chart of a modification.

### DETAILED DESCRIPTION

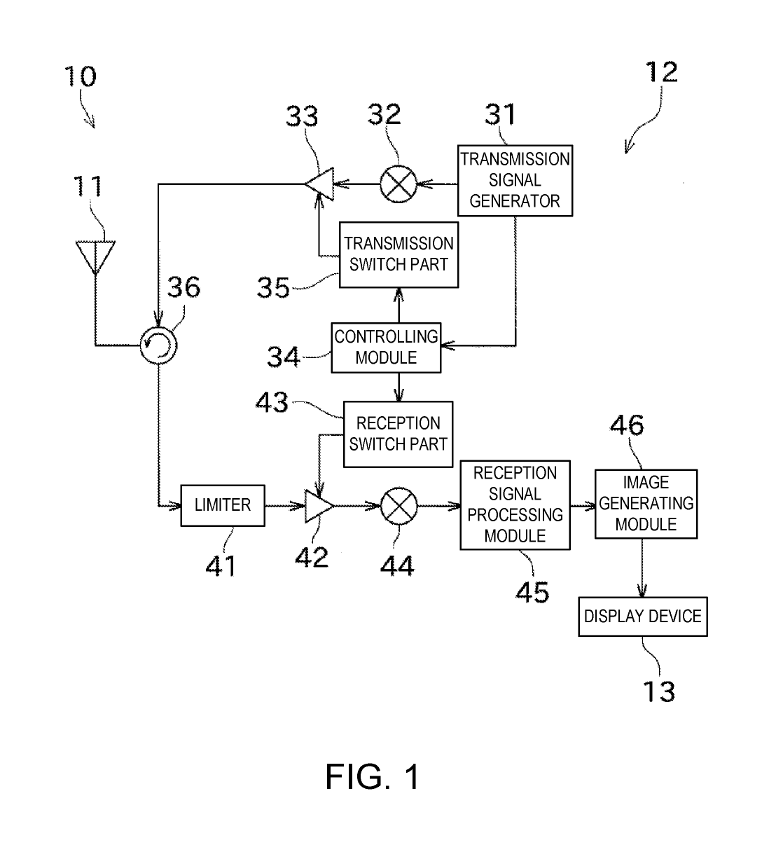

One embodiment of the present disclosure is described with reference to the accompanying drawings. In the following embodiment, an example is illustrated in which this disclosure is applied to a ship. However, the present disclosure may be applied to any kinds of vehicles having a rudder or a similar steering device, such as other watercrafts including boats, vessels, and submarines, as well as land vehicles, airplanes and spaceships. FIG. 1 is a block diagram of a radar apparatus including a radar control device according to this embodiment of the present disclosure.

A radar apparatus 10 of this embodiment may be a radar apparatus for a ship. The radar apparatus 10 may externally transmit a pulse-shaped transmission signal (pulse signal, electromagnetic wave) generated by a semiconductor element (transmission process). The radar apparatus 10 may also receive a reflection of the transmission signal, analyze this reflection by performing pulse compression etc. thereon, and thus detect a position etc. of a target object (reception process). Note that the transmission signal may alternatively be generated by, for example, a magnetron instead of a semiconductor element.

As illustrated in FIG. 1, the radar apparatus 10 may include a radar antenna 11, a signal processing device 12, and a display device 13.

The radar antenna 11 may externally transmit the transmission signal and receive the reflection of the transmission signal from a target located therearound. Hereinafter, the reflection received by the radar antenna 11 may be referred to as the reception signal. The radar antenna 11 may repeat the transmission and reception of the electromagnetic wave while rotating at a given cycle in a horizontal plane. The radar apparatus 10 may thus detect the target object around a ship on which the radar apparatus 10 is mounted (hereinafter, simply referred to as “the ship”).

Note that a radar apparatus which does not rotate its radar antenna may alternatively be used. For example, a radar apparatus having antenna elements in all circumferential directions, a radar apparatus which only detects a specific direction, such as forward, etc., are not required to rotate a radar antenna. Additionally, the radar apparatus 10 may transmit and receive the radio wave with one radar antenna, or may have a transmission radar antenna and a reception radar antenna.

The signal processing device 12 may execute a control (transmission control, reception control, analysis control, etc.) regarding the radar apparatus 10. Various components constituting the signal processing device 12 may be disposed in a housing of the radar antenna 11 (on the antenna side) or in a housing of the display device 13 (on an instruction unit side). Note that at least one or some of the components constituting the signal processing device 12 may alternatively be disposed in a separate housing from the radar antenna 11 and the display device 13.

The signal processing device 12 may include a signal generating module (period defining module) 31, a transmission mixer 32, a transmission signal amplifier 33, a controlling module (processing circuit) 34, a transmission switch part 35, and a transmission-reception switch 36 as components regarding the transmission control of the transmission signal. Note that, a circuit extending from the generation of the transmission signal to the output to the transmission-reception switch 36 may be referred to as the transmission circuit.

The signal generating module 31 may generate a transmission signal having a given waveform by specifying a pulse width, a modulation mode (a frequency modulation width and a frequency change mode) etc. This transmission signal may be converted from a digital signal into an analog signal by, for example, a D/A converter and then outputted to the transmission mixer 32. Note that the signal generating module 31 may generate a transmission trigger signal and output it to the controlling module 34. The transmission trigger signal may be a signal defining a transmission period for transmitting the transmission signal and a reception period for receiving the reception signal (described later in detail).

The transmission mixer 32 may be supplied with a local oscillation signal from a local oscillator (not illustrated). The transmission mixer 32 may raise a frequency of the transmission signal to a given transmission frequency by mixing this local oscillation signal with the transmission signal. The transmission mixer 32 may output the transmission signal with the raised frequency to the transmission signal amplifier 33.

The transmission signal amplifier 33 may be, for example, a high power amplifier, and amplify electric power of the inputted transmission signal. The transmission signal amplifier 33 (reception circuit) may be connected with a circuit (power (voltage) supply circuit, bias line) which supplies power (voltage). The transmission signal amplifier 33, in a state where power is supplied from the power supply circuit, may amplify the inputted transmission signal (hereinafter, this state is referred to as that the power source of the transmission signal amplifier 33 is ON, etc.). On the other hand, the transmission signal amplifier 33, in a state where power is not supplied from the power supply circuit, cannot amplify the inputted transmission signal (hereinafter, this state is referred to as that the power source of the transmission signal amplifier 33 is OFF, etc.). The transmission signal amplified by the transmission signal amplifier 33 may be outputted to the transmission-reception switch 36.

The controlling module 34 may execute a control regarding the transmission of the transmission signal and the reception of the reception signal. The controlling module 34 may execute a control for switching the transmission switch part 35 which is an analog switch disposed between the power supply circuit and the transmission signal amplifier 33 (reception circuit) described above. Thus, the controlling module 34 may switch ON/OFF of the power source of the transmission signal amplifier 33.

The transmission-reception switch 36 may be switchable of the transmission of the transmission signal and the reception of the reception signal therebetween. For example, when externally transmitting the transmission signal (i.e., in the transmission period), the transmission-reception switch 36 may output the transmission signal outputted from the transmission signal amplifier 33 to the radar antenna 11 (toward the outside thereof). Thus, the transmission signal may be externally transmitted. On the other hand, when receiving the reflection from the outside (i.e., in the reception period), the transmission-reception switch 36 may output the reflection (reception signal) inputted from the radar antenna 11 (from the outside) to a limiter 41 described later.

The signal processing device 12 may include the limiter 41, a reception signal amplifier 42, a reception switch part 43, a reception mixer 44, a reception signal processing module 45, and an image generating module 46, as components regarding the reception and analysis of the reception signal. Note that, a circuit extending from the reception of the reception signal by the transmission-reception switch 36 to the output of the reception signal to the image generating module 46 may be referred to as the reception circuit.

The limiter 41 may be provided to protect, when the radar antenna 11 receives a high-power signal or when a high-power transmission signal generated in the transmission circuit flows into the reception circuit, etc., the respective components of the reception circuit from these signals. The limiter 41 may suppress a signal with higher power than a given value while allowing a signal with power equal to or lower than the given value to pass through as it is. The reception signal passed through the limiter 41 may be outputted to the reception signal amplifier 42.

The reception signal amplifier 42 may be, for example, a low noise amplifier, and amplify the power of the reception signal inputted from the transmission-reception switch 36 via the limiter 41. The reception signal amplifier 42 may be connected with a circuit (power supply circuit, bias line) which supplies power. The controlling module 34 described above may perform a control for switching the reception switch part 43 which is an analog switch connected to the power supply circuit. Similar to the transmission signal amplifier 33, the reception signal amplifier 42, in a state where power is supplied from the power supply circuit, may amplify the inputted reception signal (hereinafter, this state is referred to as that the power source of the reception signal amplifier 42 is ON, etc.). On the other hand, the reception signal amplifier 42, in a state where power is not supplied from the power supply circuit, cannot amplify the inputted reception signal (hereinafter, this state is referred to as that the power source of the reception signal amplifier 42 is OFF, etc.). The reception signal amplified by the reception signal amplifier 42 may be outputted to the reception mixer 44.

The reception mixer 44 may lower a frequency of the reception signal by mixing the reception signal with the local oscillation signal similarly to the transmission mixer 32. The reception signal with the lowered frequency by the reception mixer 44 may be converted from an analog signal into a digital signal and then outputted to the reception signal processing module 45.

The reception signal processing module 45 may perform pulse compression, etc. on the reception signal. Thus, even when a pulse signal with low transmission power is transmitted, data at a high S/N ratio may be obtained. The reception signal processing module 45 may output the processed reception signal to the image generating module 46.

The image generating module 46 may generate a radar image based on the reception signal. For example, the image generating module 46 may acquire a distance from the radar antenna 11 to the target object based on a time difference between a timing at which the radar antenna 11 transmits the pulse signal and a timing at which the reflection of the pulse signal is received. Further, the image generating module 46 may obtain a direction in which the target object is located based on the orientation of the radar antenna 11 when transmitted the pulse signal. Thus, the image generating module 46 may generate the radar image graphically showing the position of the target object located around the ship. The image generating module 46 may output the generated radar image to the display device 13.

Here, some of parts constituting the signal processing device 12 (e.g., the signal generating module 31, the controlling module 34, the reception signal processing module 45 and the image generating module 46) may be achieved by an arithmetic processor such as an FPGA, an ASIC, or a CPU. For example, the signal generating module 31 etc. may include a memory, such as a ROM, storing program(s) etc., and the function of the signal generating module 31 etc. may be achieved by the arithmetic processor reading and executing the program(s) stored in the memory. Moreover, the signal generating module 31 etc. may individually be configured by separate hardware or at least partially be configured by the same hardware.

The display device 13 may display electronic data. The display device 13 may display the radar image inputted from the image generating module 46. The display device 13 may be a liquid crystal display, but it may alternatively be a different type of display (e.g., organic EL display).

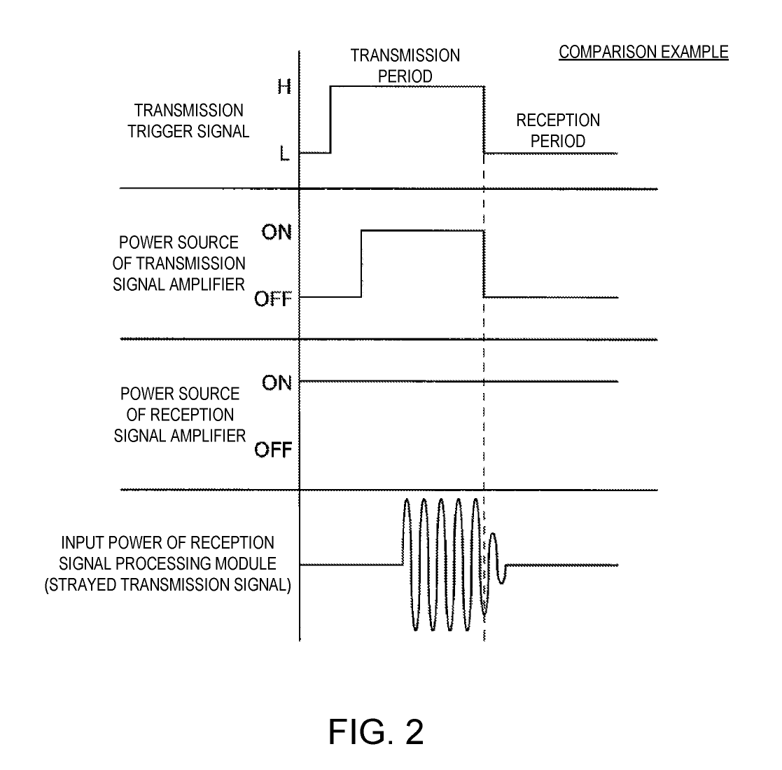

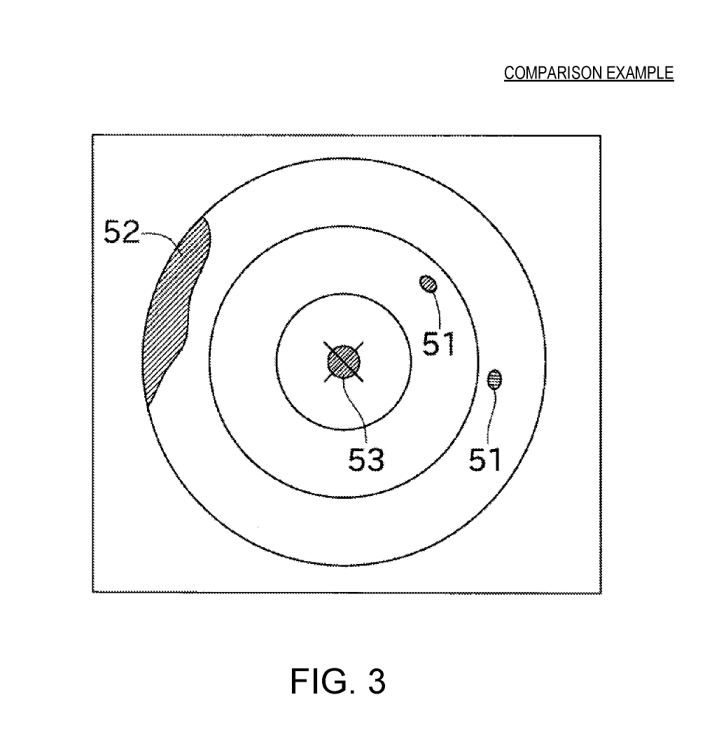

Next, a problem which occurs when the power source of the reception signal amplifier 42 is always ON is described with reference to FIGS. 2 and 3. FIG. 2 is a timing chart of a comparison example in which a power source of the reception signal amplifier 42 is always ON. FIG. 3 is a schematic diagram of a radar image of the comparison example. In the following description, switching ON/OFF of the power source of the transmission signal amplifier 33 etc. by the controlling module 34 via the transmission switch part 35 etc. may simply be referred to as, for example, “switching ON/OFF of the power source of the transmission signal amplifier 33, etc.”

As described above, the transmission trigger signal of FIG. 2 is a signal defining the transmission period and the reception period, and is generated by the signal generating module 31 and outputted to the controlling module 34. The transmission trigger signal is a digital signal having two signal levels. The transmission trigger signal with high signal level (“H” in FIG. 2) indicates being in the transmission period, and the transmission trigger signal with low signal level (“L” in FIG. 2) indicates being in the reception period. Note that the modes of the signals defining the transmission period and the reception period are arbitrary, and, for example, the transmission period and the reception period may be switched every time the pulse signal is outputted.

The power source of the transmission signal amplifier 33 is switched from OFF to ON slightly after the start of the transmission period. The external transmission of the transmission signal is performed while the power source of the transmission signal amplifier 33 is ON. Further, the power source of the transmission signal amplifier 33 is switched from ON to OFF when switching from the transmission period to the reception period. Therefore, the power source of the transmission signal amplifier 33 is always OFF during the reception period. Thus, in the reception period, even when some kinds of signal flows through the transmission circuit, the signal is prevented from being amplified and straying into the reception circuit. Note that the switching timing of the power source of the transmission signal amplifier 33 illustrated in FIG. 2 between ON/OFF is merely an example, and may be switched at different timings.

Here, the concept of “when switching from the transmission period to the reception period,” not only includes the period in which the transmission trigger signal of the signal generating module 31 shifts from High to Low, but may also include time slight before and after this period.

As described above, in the comparison example, the power source of the reception signal amplifier 42 is always ON. Therefore, in the transmission period, when the transmission signal enters the reception signal amplifier 42 through the transmission-reception switch 36 and the limiter 41, the entered transmission signal is amplified by the reception signal amplifier 42. As a result, the power (input power) of the signal inputted into the reception signal processing module 45 increases. Further, oscillation by which this signal is continuously amplified may occur. Note that FIG. 2 illustrates an input voltage of the reception signal processing module 45 when no reflection is obtained from the target object.

Then, the transmission of the transmission signal ends upon switching from the transmission period to the reception period, and the reception and analysis of the reception signal start. Immediately after the reception period starts, since the transmission signal strayed into the reception circuit still remains, the transmission signal is inputted into the reception signal processing module 45 in the reception period. Therefore, the transmission signal strayed into the reception circuit is processed as the reception signal. Then, the power of the transmission signal strayed into the reception circuit gradually decreases.

Here, immediately after the reception period starts, the radar apparatus 10 receives the reflection of the transmission signal from the target object in a close distance. Therefore, the S/N ratio of the reception signal indicating the detection result of the close distance drops. As a result, an artifact occurs near the ship in the radar image generated by the image generating module 46. More specifically, in the radar image illustrated in FIG. 3, in addition to echoes 51 of other ships and an echo 52 indicating land, a large pseudo echo 53 caused by the strayed transmission signal is displayed.

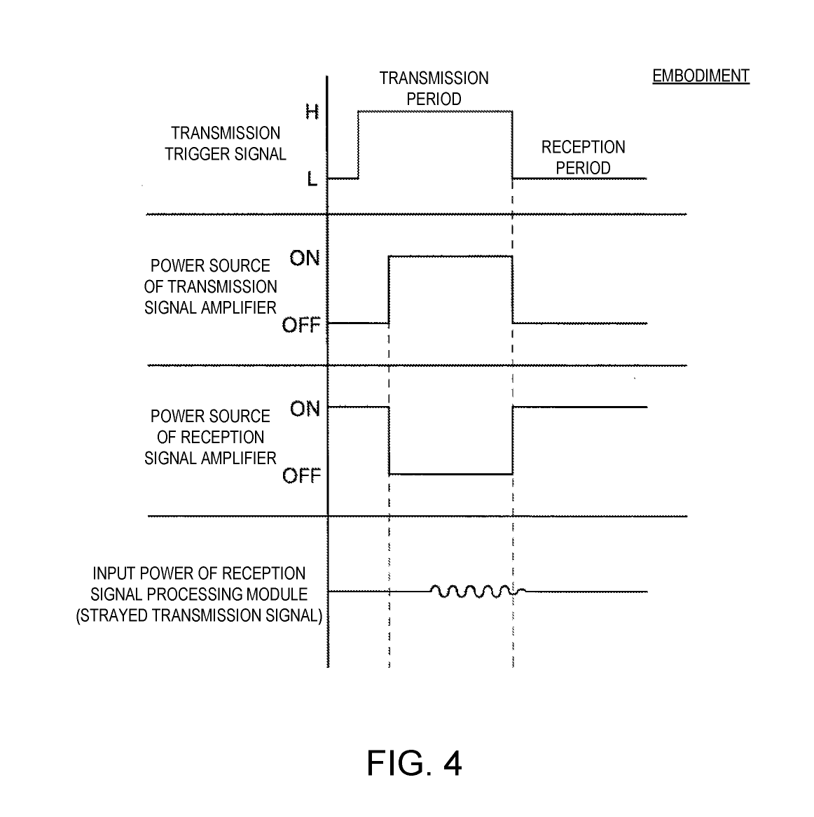

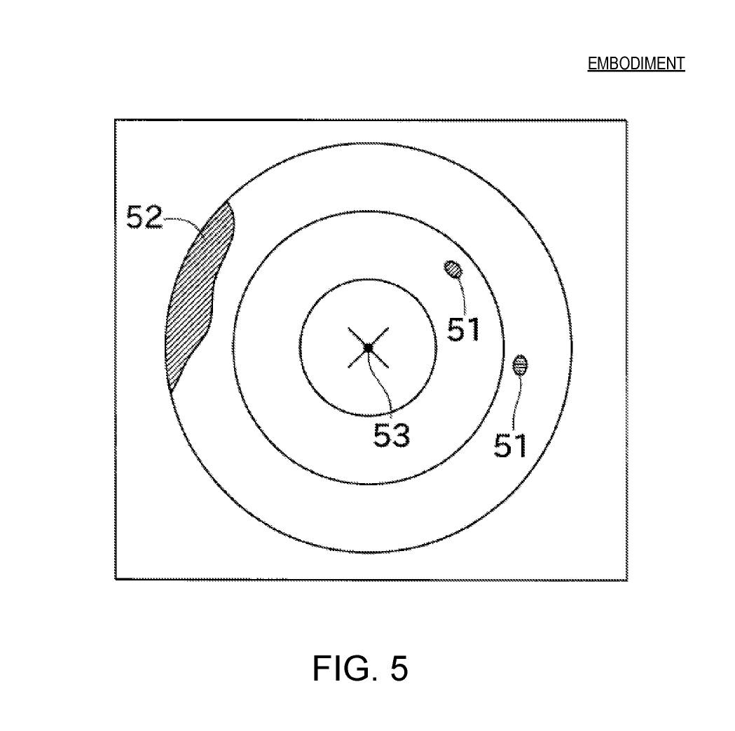

Next, processing performed by the controlling module 34 of this embodiment to reduce the straying of the transmission signal into the reception circuit and causing oscillation, or the pseudo echo 53 caused by the strayed transmission signal from being displayed largely, is described with reference to FIGS. 4 and 5. FIG. 4 is a timing chart of this embodiment. FIG. 5 is a schematic diagram of the radar image of this embodiment.

In the timing chart of FIG. 4, since the description of the transmission trigger signal and the power source of the transmission signal amplifier 33 is the same as FIG. 2, it is omitted.

In this embodiment, the power source of the reception signal amplifier 42 may not be always ON. For example, the power source of the reception signal amplifier 42 may be ON immediately after the transmission period is started. Then, simultaneously to the power source of the transmission signal amplifier 33 being switched from OFF to ON, the power source of the reception signal amplifier 42 may be switched from ON to OFF. When the power source of the transmission signal amplifier 33 is ON, there is a possibility that the amplified transmission signal strays into the reception circuit and causes oscillation, or the S/N ratio of the reception signal drops after switching to the reception period. Therefore, by turning the power source of the reception signal amplifier 42 OFF at the timing when the power source of the transmission signal amplifier 33 is turned ON, the oscillation of the transmission signal and the drop of the S/N ratio of the reception signal may be reduced. Note that, it is possible to exert similar effects also when the timing of turning the power source of the reception signal amplifier 42 OFF is set to be after the start of the transmission period but before the power source of the transmission signal amplifier 33 is turned ON.

Then, in the transmission period, similar to the comparison example, the power source of the transmission signal amplifier 33 may remain being in the ON state. Further, the power source of the reception signal amplifier 42 may remain being in the OFF state. Then, similarly to the comparison example, the power source of the transmission signal amplifier 33 may be switched from ON to OFF when switching from the transmission period to the reception period. Simultaneously, the power source of the reception signal amplifier 42 may be switched from OFF to ON when switching from the transmission period to the reception period (switching process). In other words, in the switching process, the controlling module 34, in response to the transmission trigger signal, which is inputted from the signal generating module 31, being switched to L, may switch ON/OFF of the power sources of the transmission signal amplifier 33 and the reception signal amplifier 42. By switching the power source of the reception signal amplifier 42 from OFF to ON at this timing, the reception signal inputted from the radar antenna 11 may be amplified while preventing the amplified transmission signal from straying into the reception circuit.

By switching ON/OFF of the power source of the reception signal amplifier 42 as in this embodiment, also immediately after switching from the transmission period to the reception period, the transmission signal may not stray into the reception circuit or, even if it does stray, the power of the signal may be extremely lower compared to the comparison example. Therefore, the drop of the S/N ratio of the reception signal may be reduced. As a result, as illustrated in FIG. 5, in the radar image generated by the image generating module 46, the size of the pseudo echo 53 caused by the straying of the transmission signal may be significantly reduced.

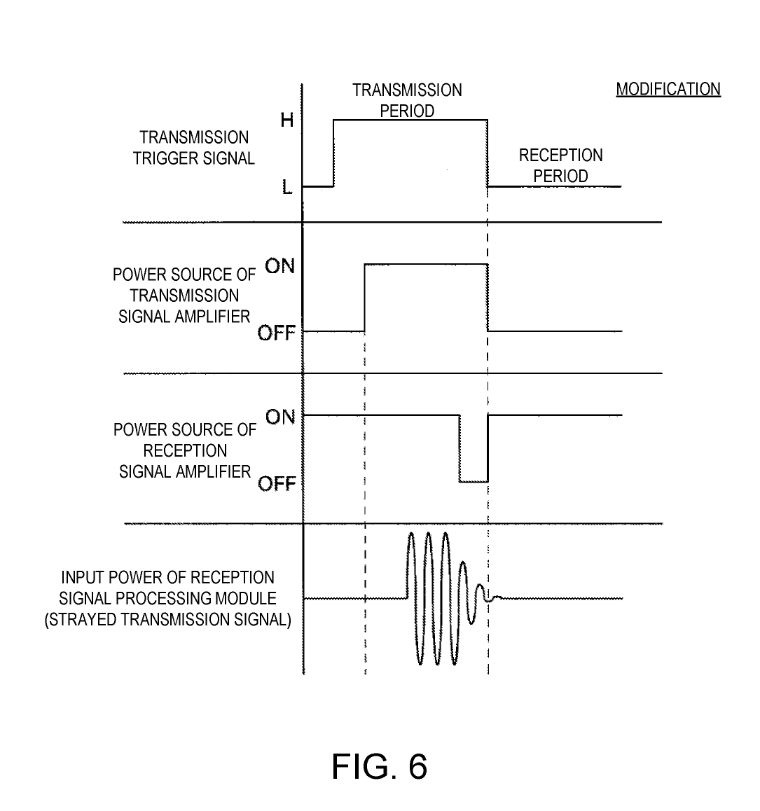

Next, a modification of the embodiment is described. FIG. 6 is a timing chart of a modification. Note that in the description of this modification, the same reference characters are applied to the same or similar members as those of this embodiment, and the description thereof may be omitted.

In the embodiment, when the power source of the transmission signal amplifier 33 is ON, the controlling module 34 may control the transmission switch part 35 and the reception switch part 43 so that the power source of the reception signal amplifier 42 is turned OFF. On the other hand, in this modification, the power source of the reception signal amplifier 42 may remain ON at the timing when the power source of the transmission signal amplifier 33 is switched from OFF to ON. Therefore, the transmission signal may stray into the reception circuit and cause oscillation.

However, by switching the power source of the reception signal amplifier 42 OFF immediately before switching from the transmission period to the reception period, the input power of the reception signal processing module 45 may be lowered. Therefore, at the start of the reception period, since the power of the transmission signal strayed into the reception circuit becomes very small, the effect that reducing the drop of the S/N ratio of the reception signal may be exerted.

As described above, the signal processing device 12 of this embodiment may include the transmission-reception switch 36, the reception signal amplifier 42, and the controlling module 34, and implement the signal processing method below. The transmission-reception switch 36 may be connected to the transmission circuit and the reception circuit. In the transmission period, the transmission-reception switch 36 may output the transmission signal inputted from the transmission circuit to the outside of the device (via the radar antenna 11), and in the reception period, it may output the reception signal inputted from the outside (via the radar antenna 11) to the reception circuit. The reception signal amplifier 42 may amplify the reception signal. The controlling module 34 may switch the power source of the reception signal amplifier 42 from OFF to ON when switching from the transmission period to the reception period.

By switching ON/OFF of the power source of the reception signal amplifier 42 in this manner, compared to the case of controlling the power source of the transmission signal amplifier 33, the straying of the transmission signal into the reception circuit may sufficiently be reduced. Particularly, by switching the power source of the reception signal amplifier 42 from OFF to ON when switching from the transmission period to the reception period, the drop of the S/N ratio of the reception signal caused by the transmission signal straying into the reception circuit may be reduced.

Further in the signal processing device 12 of this embodiment, after switching the power source of the reception signal amplifier 42 from ON to OFF in the transmission period, the controlling module 34 may keep the state where the power source of the reception signal amplifier 42 is OFF until the reception period starts.

Thus, since the power source of the reception signal amplifier 42 is OFF since relatively earlier than the switch to the reception period, the drop of the S/N ratio of the reception signal caused by the transmission signal straying into the reception circuit may be reduced even more.

Furthermore, the signal processing device 12 of this embodiment may include the transmission signal amplifier 33 which amplifies the transmission signal. While the power source of the transmission signal amplifier 33 is ON, the controlling module 34 may control the power source of the reception signal amplifier 42 to be OFF.

Thus, since the influence of the straying of the transmission signal into the reception circuit increases when the power source of the transmission signal amplifier 33 is ON, by executing the above control, the drop of the S/N ratio of the reception signal may be reduced even more.

Furthermore, the signal processing device 12 of this embodiment may include the signal generating module 31 which outputs the signal defining the transmission period and the reception period (transmission trigger signal) to the controlling module 34. The controlling module 34 may switch the power source of the reception signal amplifier 42 from ON to OFF after information of being in the transmission period is inputted from the signal generating module 31. Moreover, the controlling module 34 may switch the power source of the reception signal amplifier 42 from OFF to ON at the timing when the information of being in the reception period is inputted from the signal generating module 31.

Thus, by the period defining module defining the transmission period and the reception period and outputting the information thereof to the controlling module 34, the delay in switching ON/OFF of the power source of the reception signal amplifier 42 may be reduced.

Although the suitable embodiment and modification of the present disclosure are described above, the above configurations may be modified as follows.

The timing charts described in the embodiment and the modification are examples, and may be changed. For example, in the above embodiment and the modification, the timing of switching the power source of the transmission signal amplifier 33 from ON to OFF and the timing of switching the power source of the reception signal amplifier 42 from OFF to ON may be controlled to coincide with each other; however, the power source of the reception signal amplifier 42 may be switched from OFF to ON after switching the power source of the transmission signal amplifier 33 from ON to OFF.

In the above embodiment, although the controlling module 34 may receive the transmission trigger signal (the signal defining the transmission period and the reception period) from the signal generating module 31 which is separate hardware, the signal generating module 31 and the controlling module 34 may be the same hardware (that is, the device which defines the transmission period and the reception period and the device which controls ON/OFF of the power source of the reception signal amplifier 42 etc. may be the same).

In the above embodiment, although the example in which the present disclosure is applied to the radar apparatus for the ship is described, the present disclosure may also be applied to a radar apparatus mounted on a movable body (e.g., aircraft) other than the ship. Moreover, the present disclosure may be applied to a radar apparatus installed in a building etc. instead of the movable body. Furthermore, the present disclosure is not limited to the detection device which performs a detection around the device by transmitting and receiving electromagnetic waves, but may also be applied to a detection device which performs a detection around the device by transmitting and receiving ultrasonic waves (e.g., an underwater detection device, such as a fish finder and a sonar). Additionally, the present disclosure may also be applied to wireless communication devices which communicate with other wireless communication device(s) by transmitting a transmission signal thereto and receiving as a reception signal a signal therefrom.

### <Terminology>

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

All of the processes described herein may be embodied in, and fully automated via, software code modules executed by a computing system that includes one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processor. A processor can be a microprocessor, but in the alternative, the processor can be a controlling module, microcontrolling module, or state machine, combinations of the same, or the like. A processor can include electrical circuitry configured to process computer-executable instructions. In another embodiment, a processor includes an application specific integrated circuit (ASIC), a field programmable gate array (FPGA) or other programmable device that performs logic operations without processing computer-executable instructions. A processor can also be implemented as a combination of computing devices, e.g., a combination of a digital signal processor (DSP) and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controlling module, or a computational engine within an appliance, to name a few.

Conditional language such as, among others, “can,” “could,” “might” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Any process descriptions, elements or blocks in the flow views described herein and/or depicted in the attached figures should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C. The same holds true for the use of definite articles used to introduce embodiment recitations. In addition, even if a specific number of an introduced embodiment recitation is explicitly recited, those skilled in the art will recognize that such recitation should typically be interpreted to mean at least the recited number (e.g., the bare recitation of “two recitations,” without other modifiers, typically means at least two recitations, or two or more recitations).

It will be understood by those within the art that, in general, terms used herein, are generally intended as “open” terms (e.g., the term “including” should be interpreted as “including but not limited to,” the term “having” should be interpreted as “having at least,” the term “includes” should be interpreted as “includes but is not limited to,” etc.).

For expository purposes, the term “horizontal” as used herein is defined as a plane parallel to the plane or surface of the floor of the area in which the system being described is used or the method being described is performed, regardless of its orientation. The term “floor” can be interchanged with the term “ground” or “water surface.” The term “vertical” refers to a direction perpendicular to the horizontal as just defined. Terms such as “above,” “below,” “bottom,” “top,” “side,” “higher,” “lower,” “upper,” “over,” and “under,” are defined with respect to the horizontal plane.

As used herein, the terms “attached,” “connected,” “mated,” and other such relational terms should be construed, unless otherwise noted, to include removable, moveable, fixed, adjustable, and/or releasable connections or attachments. The connections/attachments can include direct connections and/or connections having intermediate structure between the two components discussed.

Numbers preceded by a term such as “approximately,” “about,” and “substantially” as used herein include the recited numbers, and also represent an amount close to the stated amount that still performs a desired function or achieves a desired result. For example, the terms “approximately,” “about,” and “substantially” may refer to an amount that is within less than 10% of the stated amount. Features of embodiments disclosed herein are preceded by a term such as “approximately,” “about,” and “substantially” as used herein represent the feature with some variability that still performs a desired function or achieves a desired result for that feature.

It should be emphasized that many variations and modifications may be made to the above-described embodiments, the elements of which are to be understood as being among other acceptable examples. All such modifications and variations are intended to be included herein within the scope of this disclosure and protected by the following claims.

What is claimed is:

1. A signal processing device, comprising:
a transmission-reception switch connected to transmission circuitry, reception circuitry, and an antenna, and configured to output, in a transmission period, a transmission signal inputted from the transmission circuitry to the antenna and output, in a reception period, a reception signal inputted from the antenna to the reception circuitry;
a reception signal amplifier configured to amplify the reception signal; and
processing circuitry configured to switch a power source of the reception signal amplifier from OFF to ON when switching from the transmission period to the reception period.

2. The signal processing device of claim 1, wherein the processing circuitry is further configured to:
switch the power source of the reception signal amplifier from ON to OFF in the transmission period, and then
keep the reception signal amplifier OFF until the reception period starts.

3. The signal processing device of claim 1, further comprising a transmission signal amplifier configured to amplify the transmission signal,
wherein, when a power source of the transmission signal amplifier is ON, the processing circuitry is further configured to control the power source of the reception signal amplifier to be OFF.

4. The signal processing device of claim 2, further comprising a transmission signal amplifier configured to amplify the transmission signal,
wherein, when a power source of the transmission signal amplifier is ON, the processing circuitry is further configured to control the power source of the reception signal amplifier to be OFF.

5. The signal processing device of claim 1, wherein the processing circuitry is further configured to:
switch the power source of the reception signal amplifier from ON to OFF when entering the transmission period, and
switch the power source of the reception signal amplifier from OFF to ON when entering the reception period.

6. The signal processing device of claim 4, wherein the processing circuitry is further configured to:
switch the power source of the reception signal amplifier from ON to OFF when entering the transmission period, and
switch the power source of the reception signal amplifier from OFF to ON when entering the reception period.

7. The signal processing device of claim 1, wherein a reflection of the transmission signal that is an electromagnetic wave transmitted to the antenna is processed as the reception signal.

8. The signal processing device of claim 6, wherein a reflection of the transmission signal that is an electromagnetic wave transmitted to the antenna is processed as the reception signal.

9. A radar apparatus, comprising:
the signal processing device of claim 1; and
a radar antenna configured to at least receive a reflection of the transmission signal.

10. A radar apparatus, comprising:
the signal processing device of claim 8; and
a radar antenna configured to at least receive a reflection of the transmission signal.

11. A method of processing a signal, comprising:
outputting, in a transmission period, a transmission signal inputted from transmission circuitry to an antenna;
outputting, in a reception period, a reception signal inputted from the antenna to reception circuitry;
amplifying the reception signal; and
switching a power source of a reception signal amplifier from OFF to ON when switching from the transmission period to the reception period.
